(19) United States
(12) Patent Application Publication
(10) Pub. No.: US 2021/0159892 A1
(43) Pub. Date: May 27, 2021

(54) TIME-DELAY CIRCUIT FOR A DIGITAL SIGNAL, PARTICULARLY FOR A CLOCK SIGNAL

(71) Applicant: Renesas Electronics America Inc., Milpitas, CA (US)

(72) Inventors: Vikas AGRAWAL, San Jose, CA (US); Feng QIU, Fremont, CA (US); Cheng Wen HSIAO, San Jose, CA (US); Yimu GUO, Lexington, CA (US)

(21) Appl. No.: 16/953,241

(22) Filed: Nov. 19, 2020

(30) Foreign Application Priority Data
Nov. 21, 2019 (EP) 19210570.8

(51) Int. Cl. H03K 5/06; H03K 5/15

(52) U.S. Cl. CPC H03K 5/06; H03K 2005/00058; H03K 5/1506

(57) ABSTRACT

The invention relates to a time-delay circuit (1) for a digital signal (3), particularly for a clock signal, comprising:

an input (2) for the digital signal (3);
an oscillator (4) for generating an internal clock signal (5);
at least one delay channel (6) adding a certain delay to the digital input signal (3) based on the internal clock signal (5); and
an output (7) for a delayed digital signal (8).

### RELATED APPLICATIONS

The present disclosure claims priority to EP application EP19210570.8, filed on Nov. 21, 2019, which is herein incorporated by reference in its entirety.

### FIELD OF THE DISCLOSURE

Embodiments of the present disclosure relate to a time-delay circuit for a digital signal, particularly for a clock signal.

### DISCUSSION OF RELATED ART

Time-delay circuits are widely used in electronic circuits, for example for delaying the clock signals of electronic circuits. Time-delay circuits known from the prior art commonly use Resistor-Capacitor (RC) components producing the time delay between the input signal and the delayed output signal. However, the use of RC-components has limitations on minimum pulse width and frequency of operation. These time-delay circuits further suffer from large variations over process corners and temperature corners, which requires components trimming during manufacturing, which introduces higher manufacturing costs.

Other architectures known from the prior art, like Delayed Locked Loop (DLL) circuits, are complex and costly. Due to the complexity these circuits have a large footprint regarding the required chip size.

### SUMMARY

Some embodiments according to the present disclosure provide a time-delay circuit that is simple and easy to manufacture, requires a minimum of space, has minimum power consumption and can be used over a wide frequency range, especially with high frequencies.

According to some embodiments, a time-delay circuit for a digital signal, particularly for a clock signal, includes
an input for the digital signal;
an oscillator for generating an internal clock signal;
at least one delay channel adding a certain delay to the digital input signal based on the internal clock signal; and
an output for a delayed digital signal.

The time-delay circuit according to some embodiments comprises an oscillator for generating an internal clock signal. This internal clock signal is used by the at least one delay channel to produce a certain time-delay. Since the delay of the at least one delay channel bases on the internal clock signal and not on RC components the time-delay circuit according to the invention can support higher input frequencies at the input. In general, the supported input frequencies only relate to the frequency of the internal clock signal produced by the oscillator. The produced time delay must be smaller than the period of the maximum supported frequency, because otherwise the next input pulse would arrive before the previous pulse is delayed and the next pulse would be missed. Thus, the maximum supported frequency is 1/T_{delay} produced by the time-delay circuit. Furthermore, the time-delay circuit according to some embodiments is easy to manufacture, requires a minimum of space and the required power for the oscillator and the at least one delay channel is also limited.

According to some embodiments, the time-delay circuit comprises multiple delay channels, wherein each delay channel adds a certain delay to a part of the digital input signal based on the internal clock signal, and wherein the delayed digital signal is an aggregation of the delayed parts of the input signal by the multiple delay channels.

According to some embodiments, the input signal is split into parts and assigned to different channels of the time-delay circuit. The parts of the input signal are advantageously separate pulses of the digital input signal. For example, the time-delay circuit comprises two delay channels, so that the incoming pulse of the digital input signal are alternatively respectively sequentially assigned to the two respectively more delay channels. Thus, the maximum supported frequency has been doubled or further enhanced for more delay channels. The supported frequency can be further increased by using more delay channels. The delayed parts of the input signal, i.e. the assigned pulses, are aggregated at the output to produce the total delayed signal.

Pursuant to a some embodiments the multiple delay channels have the same or different delays. If the multiple delay channels have the same delay, the parts, i.e. pulses, of the input signal are equally assigned to the multiple channels and if the multiple delay channels have different delays, the parts of the input signal are preferably unequally distributed to the multiple channels, particularly in such a ratio that the aggregated output signal is a delayed version of the input signal.

In some embodiments the certain time delay of the delay channel is adjustable, particularly for each delay channel. The certain delay of a delay channel is for example adjusted by changing the division rate of the internal clock signal. By adjusting the certain delays of the delay channels the time-delay circuit according to some embodiments can be customized for different applications.

According to some embodiments the time-delay circuit further comprises a delay selector for adjusting the certain delay of the at least one delay channel. The delay selector can for example adjust the division rate of the internal clock signal for each delay channel.

Pursuant to some embodiments the at least one delay channel adjusts the certain time delay by dividing the internal clock signal, preferably within each channel for multiple delay channels. Such a frequency division is easy to implement and has low power consumption.

In some embodiments the oscillator is a process, voltage and temperature compensated oscillator. Thus, the time-delay circuit according to the invention is mainly independent of process, voltage and temperature variations.

Pursuant to some embodiments the time-delay circuit further includes an edge detector for the digital input signal. The edge detector assigns the rising edge of the digital input signal to a first part of the delay channel and the falling edge of the digital input signal to a second part of the delay channel Thus, the first part of the delay channel is designed to delay the rising edge of the digital input signal and the second part of the delay channel is designed to delay the falling edge of the delay channel. For example, each part of the delay channel comprises separate delay components for delaying the rising respectively falling edge of the digital input signal. Thus, the digital input signal is first divided into the rising and falling edges and afterwards these separated rising and falling edges are assigned to the first part and second part of the delay channel. In this way short input pulses can be processed.

According to some embodiments the edge detector is part of the input of the time-delay circuit and/or part of the delay channel, particularly of each of the multiple delay channels.

In some embodiments the output of the delay channel aggregates the delayed signals for rising edge and the falling edge and thereby provides the delayed output signal of the delay channel. In a single channel time-delay circuit the output of the delay channel corresponds to the output of the time-delay circuit and in a multi-channel time-delay circuit the delayed outputs of the multiple delay channels are aggregated by the output of the time-delay circuit.

Pursuant to a some embodiments the at least one delay channel comprises multiple delay components, each providing a delay to the input signal of the delay channel. The certain delay of the at least one delay channel is defined by a selection of one or more of the delays provided by the multiple delay components. Thus, one or more of the multiple delay components can be selected define the certain delay of the delay channel. The selection of the delay components can be performed by the delay selector for adjusting the certain delay of the at least one delay channel.

In some embodiments the at least one delay channel comprises a multiplexer for selecting the one or more delays provided by the multiple delay components. Thus, the input signal of the delay channel is forwarded to all delay components and the multiplexer selects the relevant delayed output signals of the multiple delay components of the delay channel to provide the certain delay of the delay channel. Therefore, the input signal of the delay channel is processed, i.e. delayed, by all delay components, but the multiplexer selects only the relevant signals of multiple delay components to provide the certain delay of the delay channel. The multiplexer can be for example controlled by the delay selector.

Pursuant to some embodiments the multiple delay components are programmable, i.e. the delay provided by the delay components can be adjusted by programming. In this way the provided delay can be further adjusted.

According to some embodiments the oscillator is programmable. Thus, the frequency of the oscillator can be adjusted to different frequencies. Thereby the time-delay circuit according to the invention can be customized for different applications.

The time-delay circuit according to some embodiments can be integrated into another integrated circuit providing the digital input signal and/or using the delayed digital output signal of the time-delay circuit. Alternatively, the time-delay circuit according to some embodiments can be implemented in a separate integrated circuit and connected to other circuits for example by means of a printed circuit board.

### SHORT DESCRIPTION

In the following embodiments of this disclosure will be explained with respect to the following figures.

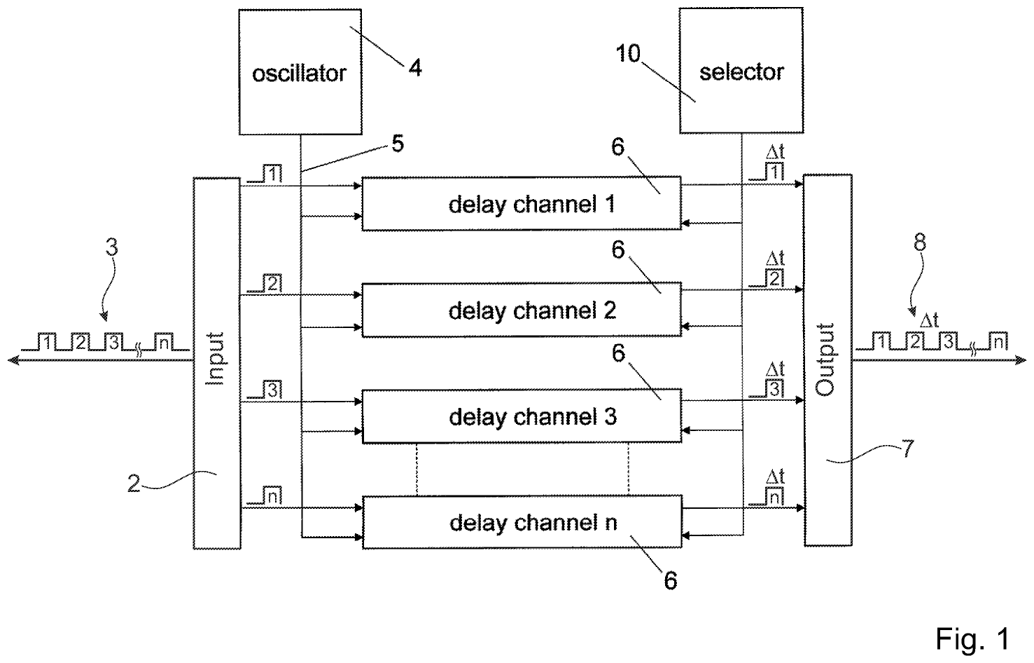

FIG. 1 illustrates a block diagram of a first embodiment of a time-delay circuit according to some embodiments of the invention.

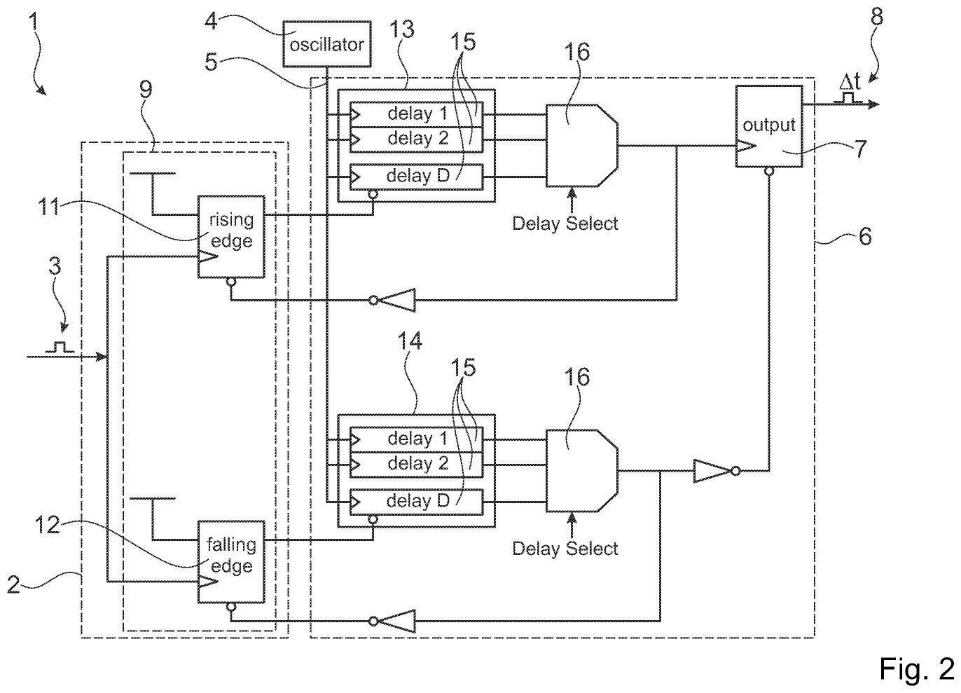

FIG. 2 illustrates a block diagram of a second embodiment of a time-delay circuit according to some embodiments of the invention.

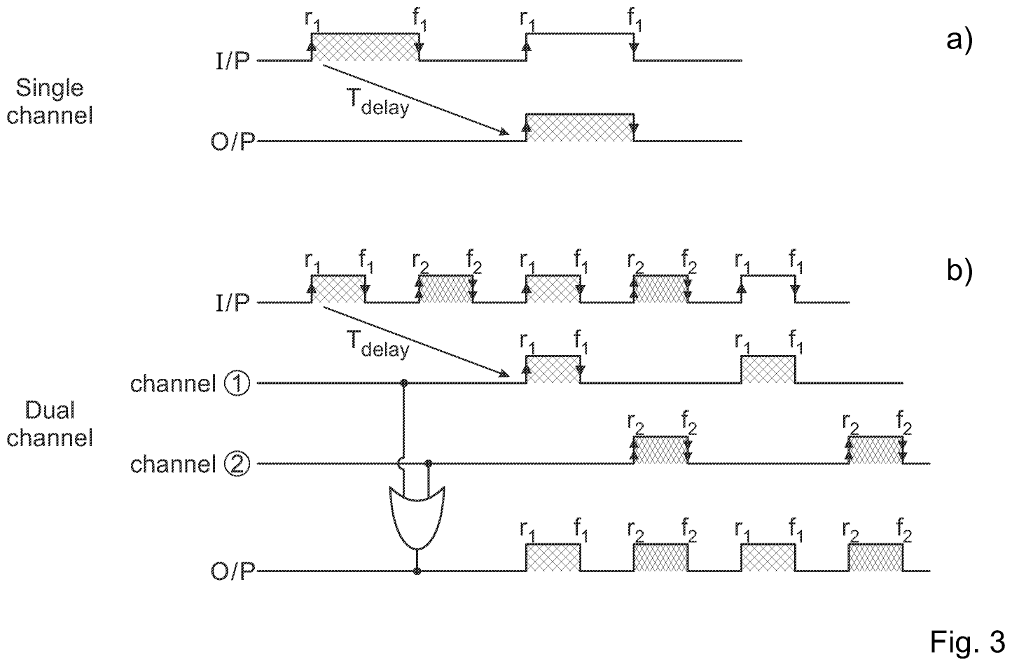

FIG. 3 illustrates signal diagrams for a single channel and dual channel time-delay circuit according to some embodiments of the invention.

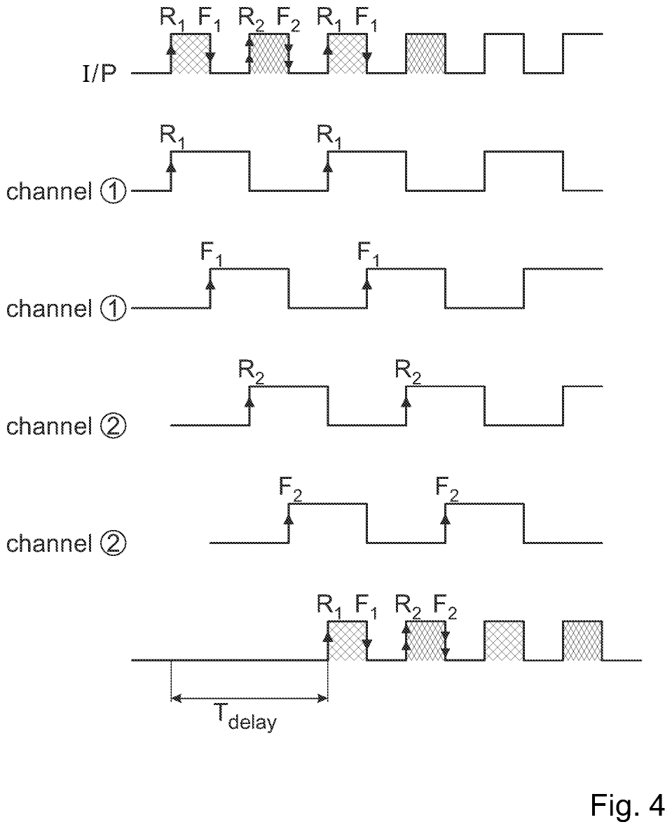

FIG. 4 illustrates a signal diagram for a dual channel time-delay circuit with different delay components for the rising and falling edges.

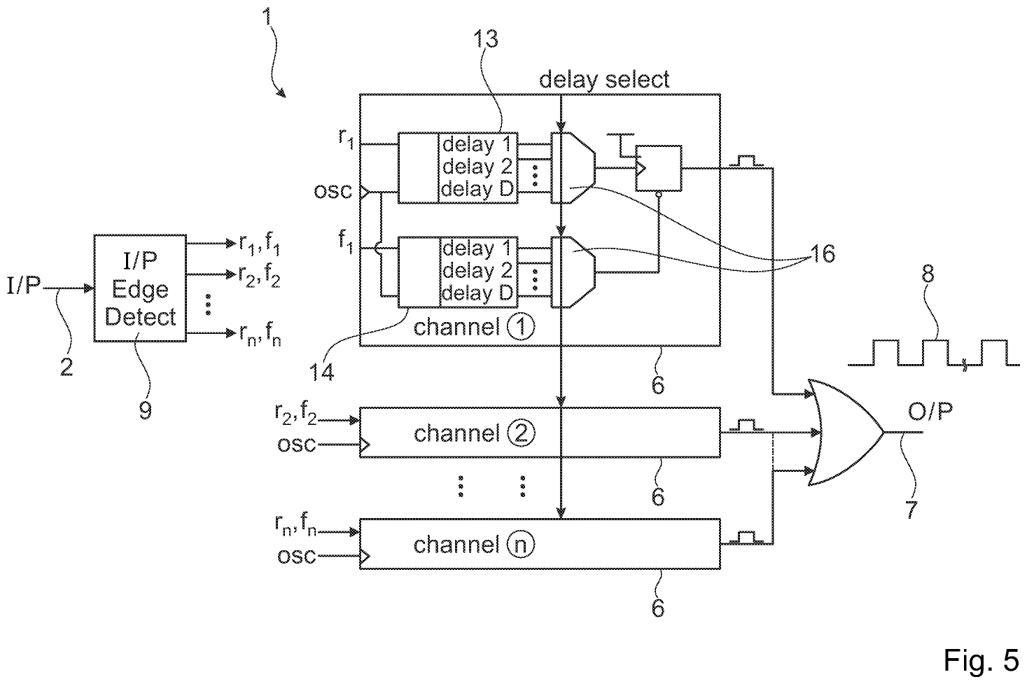

FIG. 5 illustrates a schematic block diagram of a third embodiment of a time-delay circuit according to the invention.

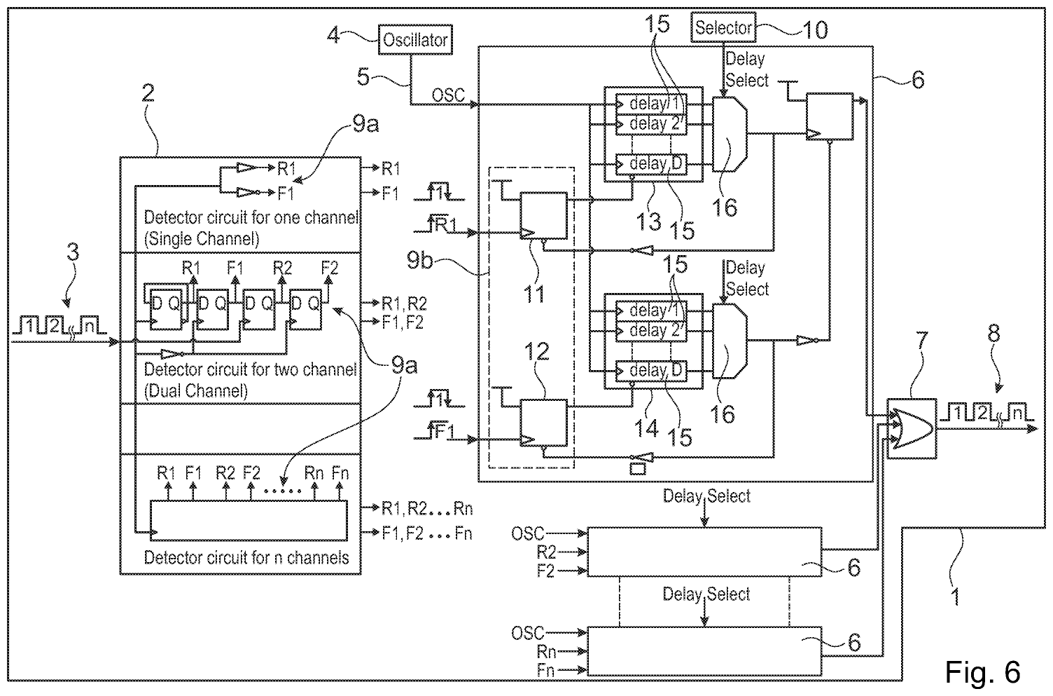

FIG. 6 illustrates a schematic block diagram of different embodiments of time-delay circuits according to the invention combined in one diagram.

### DETAILED DESCRIPTION

FIG. 1 shows a block diagram of a first embodiment of a time-delay circuit 1 for a digital signal 3, particularly a clock signal, according to the invention. The time-delay circuit 1 comprises an input 2 for the digital signal 3 and an output 7 for a delayed digital signal 8.

The time-delay circuit 1 further comprises an oscillator 4 for generating an internal clock signal 5 and multiple delay channels 6. Each delay channel 6 adds a certain delay to a part of the digital input signal 3 based on the internal clock signal 5. Advantageously, the pulses of the digital input signal 3 are sequentially divided to the different delay channels 6, thereby enhancing the maximum supported input frequency. According to the embodiment of FIG. 1 the time-delay circuit 1 comprises n channels and the first pulse of the input signal 3 is assigned to the first delay channel 6, the second pulse of the input signal 3 is assigned to the second delay channel 6, the third pulse of the input signal 3 is assigned to the third delay channel 6, up to the n-th pulse of the input signal 3 that is assigned to the n-th delay channel 6.

According to some embodiments the delayed digital signal 8 of the output 7 is an aggregation of the delayed signals of the multiple delay channels 6.

Preferably, the certain delay of the delay channels 6 is adjustable for each delay channel 6. In this way the time-delay circuit 1 can be customized for a particular application, i.e. for providing a certain delayed digital signal 8 at the output 7.

For example, the certain delay of the delay channels 6 is adjustable by dividing the internal clock signal 5 within each delay channel 6. The delay channels 6 can have the same or different delays, for example by using the same division or different divisions of the internal clock signal 5. If the pulses of the digital input signal 3 are sequentially distributed to the different delay channels 6, these delay channels 6 preferably have the same delay.

The time-delay circuit 1 of FIG. 1 further comprises a delay selector 10 for adjusting the certain delay of the multiple delay channels 6, e.g. by amending the division of the internal clock signal 5 within each delay channel 6.

Advantageously, the oscillator 4 is a process, voltage and temperature compensated oscillator 4. Thus, the time-delay circuit 1 according to some embodiments is less susceptible to process, voltage and temperature variations.

Furthermore, the oscillator 4 is programmable, so that the internal clock signal 5 can be amended before and/or during operation. This further enables customization of the time-delay circuit 1 for different applications and/or variations during operation.

FIG. 2 shows a block diagram of a second embodiment of a time-delay circuit 1 for a digital signal 3, particularly a clock signal, according to some embodiments. The time-delay circuit 1 of FIG. 2 comprises an input 2 for the digital signal 3, an oscillator 4 for generating an internal clock signal 5, single delay channel 6 and an output 7 for a delayed signal 8. The output of the single delay channel 6 is also the output 7 of the time-delay circuit 1.

According to the second embodiment of FIG. 2 the input 2 comprises an edge detector 9 for the digital input signal 3. The edge detector 9 particularly comprises a rising edge detector 11 (also referred to as rising edge delay enable) and a falling edge detector 12 (also referred to as falling edge delay enable) for detecting the respective edges of the digital input signal 3.

The edge detector 9 assigns the rising edge and the falling edge of the digital input signal 3 to different parts 13, 14 of delay channel 6. Particularly, the delay channel 6 has two separate parts 13, 14, one part 13 for the rising edge of the digital input signal 3 and one part 14 for the falling edge of the digital input signal 3.

According to the second embodiment of FIG. 2 each part 13, 14 of the delay channel 6 comprises multiple delay components 15. Each delay component 15 provides a delay to the input signal 3 of the delay channel 6. In this embodiment the rising and falling edges of the input signal are assigned to parts 13, 14 of the delay channel and each part of the delay channel 6 comprises multiple delay components providing the certain delay for the rising respectively falling edge of the input signal 3. The certain delay of the delay channel 6 is defined by a selection of one or more of the delays provided by the multiple delay components 15.

The time delay circuit 1, particularly the delay channel 6, can further comprises two multiplexers 16, one for each group 13, 14 of delay channels 6. The signals of the multiple delay components 15 of one group 13, 14 are the input of one multiplexer 16 and the multiplexer 16 can select one or more of these delay component signals and forward these signals to the output 7.

The output of the delay channel aggregates the delayed signals for the rising edge and the falling edge and corresponds to the output 7 of the time-delay circuit 1.

Preferably the delay of the delay components 15 is adjustable for each delay component 15. Advantageously, the delay of the delay components 15 is programmable, i.e. can be modified/adapted. For example, the delay of the delay components 15 is adjustable by dividing the internal clock signal 5 within each delay component 15.

The delay channels 6 can have the same or different delays.

Like in the first embodiment shown in FIG. 1 the oscillator 4 is a process, voltage and temperature compensated oscillator 4 and preferably is programmable.

FIG. 3a shows a signal diagram for a single channel 6 time-delay circuit 1 according to some embodiments. The upper part shows the digital input signal 3 and the lower part shows the delayed output signal 8. The rising edges r1 and falling edges f1 are marked by corresponding arrows on the signals. The signal diagram for FIG. 3a could refer to the second embodiment of a time-delay circuit 1 shown FIG. 2.

FIG. 3b shows a signal diagram for a dual channel 6 time-delay circuit 1 according to some embodiments. The input signal 3 is sequentially, i.e. alternating, assigned to the first channel 6 and second channel 6 of the time-delay circuit 1. The first and second channel 6 provide the same time delay. The output signal 8 is an aggregation of the delayed signals of the first and second delay channel 6, symbolized by the OR-element in FIG. 3b. The rising and falling edges are correspondingly marked as r1, r2 respectively f1, f2 or a single or double arrow in FIG. 3b. The rising and falling edges can be delayed by separate delay components 15, as disclosed with respect to FIG. 2 and shown in more detail in FIG. 4.

FIG. 4 shows a signal diagram for a dual channel 6 time-delay circuit 1 with different parts 13, 14 for the rising and falling edges. The rising edges r1 of the input signal 3 are assigned to a first part 13 of the first delay channel 6 and the falling edges f1 of the input signal 3 are assigned to a second part 14 of the first delay channel 6. Accordingly, the rising edges r2 of the input signal 3 are assigned to a first part 13 of the second channel 6 and the falling edges f2 of the input signal 3 are assigned to a second part 14 of the second channel 6.

FIG. 5 shows a schematic block diagram of a third embodiment of a time-delay circuit 1 according to the invention. The digital input signal 2 is first divided into rising edges r1-rn and falling edges f1-fn, wherein n is the number of different delay channels 6 of the time-delay circuit 1. The rising and falling edges r1-rn, f1-fn are afterwards sequentially assigned to the different delay channels 6, number 1-n accordingly. Each delay channel 6 comprises a first group 13 of delay components 15 and a second group 14 of delay components 15. The rising edges r1-rn of the signal are processed by the first group 13 of the respective delay channel 6 and the falling edges f1-fn of the signal are processed by the second group 14 of the respective delay channel 6. The delay components 15 in each group 13, 14 provide different delays to the input signal assigned to the delay channel 6, specifically to the rising edge r1-rn or falling edge f1-fn of that signal. A multiplexer 16 selects the signal of that delay component 15 or multiple delay components 15 of both groups 13, 14 that provide the current desired delay. At the output of each delay channel 6 the rising edges r1-rn and falling edges f1-fn are aggregated. The signals of all delay channels 6 numbered 1 to n are aggregated to provide the final output signal 8 at the output 7 of the time-delay circuit shown in FIG. 5. The internal components of the delay channels 6 numbered 2 to n are identical to the details shown in the first delay channel 6. Thus, the third embodiment shown in FIG. 5 is a combination of the first embodiment shown in FIG. 1 and the second embodiment shown in FIG. 2.

FIG. 6 shows a schematic block diagram of different embodiments of time-delay circuits 1 according to some embodiments of the invention combined in one diagram.

A time-delay circuit 1 for a digital signal 3, particularly for a clock signal, in general comprises an input 2 for the digital signal 3, an oscillator 4 for generating an internal clock signal 5 and one or more delay channels 6, each adding a certain delay to the digital signal 3 based on the internal clock signal, and an output 7 for a delayed digital signal 8.

The internal layout of the input 2 for the digital signal 3 depends on the number of delay channels 6. In case of a single delay channel 6 the pulse of the digital signal 3 are sequentially forwarded to the single delay channel 6. This variant is shown in the upper part of the input 2 in FIG. 6. If the time-delay circuit 1 comprises two separate delay channels 6, the input 2 alternatingly assigns the pulses of the digital input signal 3 to the two delay channels 6. This variant is shown in the middle part of the input 2 in FIG. 6. Alternatively, the time-delay circuit 1 can comprise multiple delay channels 6. In this variant, the input 2 sequentially assigns the pulses of the digital input signal 3 to the different delay channels 6, which is shown in the lower part of the input 2 in FIG. 6. The advantage of multiple delay channels 6 is that higher frequencies of the digital input signal 3 can be supported.

Each delay channel 6 adds a certain delay to the digital input signal 3 respectively a part of the digital input signal 3 in case of multiple delay channels. For multiple delay channels 6, the delayed digital signal 8 at the output 7 of the time-delay circuit 1 is an aggregation of the delayed parts of the input signal 3 by the multiple delay channels 6. Preferably, the multiple delay 6 channels have the same certain delay, so that digital signal 8 at the output 7 is only delayed compared to the digital input signal 3, without changing the digital signal.

In an advantageous embodiment of the invention the certain delay of the one or more delay channels 6 is adjustable, for example using a delay selector 10. The certain delay of the one or more delay channels 6 is for example adjustable by dividing the internal clock signal 5.

Advantageously, the oscillator 4 is a process, voltage and temperature compensated oscillator 4. Furthermore, the oscillator 4 can be programmable.

The time-delay circuit 1 can further comprise an edge detector 9 for the digital input signal 3, wherein the edge detector 9 assigns the rising edge of the digital input signal 3 to a first part of the delay channel 6 and the falling edge of the digital input signal 3 to a second part of the delay channel 6.

According to FIG. 6 the edge detector 9 comprises a first part 9a, referred to as edge detect, separating the rising and falling edges of the digital input signal 3 depending on the number of delay channels 6, particularly by generating pulses R1, F1, R2, F2 to Rn, Fn for the rising and falling edges of the digital input signal 3. This first part 9a of the edge detector 9 is part of the input 2 according to FIG. 6. In case of a single delay channel 6, the first part 9a of the edge detector 9 generates pulses R1 and F1 for the rising and falling edges of the digital input signal 3. In case of two delay channels 6, the first part 9a of the edge detector 9 generates pulses R1, F1 and R2, F2 for alternating pulses of the digital input signal 3. In case of n delay channels 6 the first part 9a of the edge detector 9 generates pulses R1, F1, R2, F2 up to Rn, Fn for sequential pulses of the digital input signal 3. Each delay channels 6 comprises a second part 9b, referred to as delay enable, of the edge detector 9 that detects the generated pulses R1, F1, R2, F2 to Rn, Fn, wherein the first delay channel 6 receives the signals R1, F1, the second delay channel 6 receives the signal R2, F2 up to the n-th delay channel 6 receiving the signal Rn, Fn. The second part 9b of the edge detector 9 in each delay channel 6 comprises a rising edge detector 11 and a falling edge detector 12. Thus, according to the embodiment of FIG. 6 the edge detector 9 is part of the input 2 and each delay channel 6.

The rising and falling edges of the digital input signal 3 are delayed separately within each delay channel 6 and the output of the delay channel 6 aggregates the delayed signals for the rising edge and falling edge.

According to the embodiment shown in FIG. 6 each delay channel 6 comprises multiple delay components 15 each providing a delay to the input signal of the delay channel 6, wherein the certain delay of the at least one delay channel 6 is defined by a selection of one or more of the delays provided by the multiple delay components 15. Particularly, each delay channel 6 comprises a first part 13 and a second part 14 of delay components 15, wherein the first part 13 delays the rising edge of the input signal of the delay channel 6 and the second part 14 delays the falling edge of the input signal of the delay channel 6. The delay channels 6 comprise multiplexer 16 for the first and second part 13, 14 of delay components 15, wherein the multiplexer 16 selects one or more delays provided by the multiple delay components 15. According to FIG. 6 the multiplexers 16 are controlled by the selector 10.

### LIST OF REFERENCE NUMERALS

1 time-delay circuit
2 input
3 digital signal
4 oscillator
5 internal clock signal
6 delay channel
7 output
8 delayed digital signal
9 edge detector
9a edge detector (edge detect)
9b edge detector (delay enable)
10 channel selector
11 rising edge detector
12 falling edge detector
13 first part of channel group
14 second part of channel group
15 delay component
16 multiplexer

1. A time-delay circuit for a digital signal, comprising:
an input for the digital signal;
an oscillator configured to generate an internal clock signal;
at least one delay channel configured to add a certain delay to the digital input signal based on the internal clock signal; and
an output configured to provide for a delayed digital signal.

2. The time-delay circuit according to claim 1,
wherein the time-delay circuit comprises multiple delay channels, wherein each delay channel adds a certain delay to a part of the digital input signal based on the internal clock signal, and wherein the delayed digital signal is an aggregation of the delayed parts of the input signal by the multiple delay channels.

3. The time-delay circuit according to claim 2,
wherein the multiple delay channels have the same or different delays.

4. The time-delay circuit according to claim 1,
wherein the certain delay of the at least one delay channel is adjustable, particularly for each delay channel.

5. The time-delay circuit according to claim 4,
further comprising a delay selector for adjusting the certain delay of the at least one delay channel.

6. The time-delay circuit according to claim 1,
wherein the certain delay of the at least one delay channel is adjustable by dividing the internal clock signal, preferably within each channel for multiple delay channels.

7. The time-delay circuit according to claim 1,
wherein the oscillator is a process, voltage and temperature compensated oscillator.

8. The time-delay circuit according to claim 1, further comprising an edge detector for the digital input signal, wherein the edge detector assigns a rising edge of the digital input signal to a first part of the delay channels and a falling edge of the digital input signal to a second part of the delay channel.

9. The time-delay circuit according to claim 8,
wherein the edge detector is part of the input of the time-delay-circuit and/or part of the delay channel, particularly of each of the multiple delay channels.

10. The time-delay circuit according to claim 8,
wherein the output of the delay channel aggregates the delayed signals for the rising edge and the falling edge.

11. The time-delay circuit according to claim 1, wherein the at least one delay channel comprises multiple delay components each providing a delay to the input signal of the delay channel, wherein the certain delay of the at least one delay channel is defined by a selection of one or more of the delays provided by the multiple delay components.

12. The time-delay circuit according to claim,
wherein the at least one delay channel comprises a multiplexer for selecting the one or more delays provided by the multiple delay components.

13. The time-delay-circuit according to claim 10,
wherein the multiple delay components are programmable.

14. The time-delay circuit according to claim 1,
wherein the oscillator is programmable.
